(19) United States
(12) Patent Application Publication
(10) Pub. No.: US 2025/0212573 A1
(43) Pub. Date: Jun. 26, 2025

(54) ENHANCED WIRE BOND CONFIGURATION FOR A LIGHT EMITTING DIODE PACKAGE

(71) Applicant: Dominant Opto Technologies Sdn Bhd., Melaka (MY)

(72) Inventors: LOW TEK BENG, MELAKA (MY); KAM PING ANG, MELAKA (MY); LIM CHEE SHENG, MELAKA (MY)

(21) Appl. No.: 18/602,910

(22) Filed: Mar. 12, 2024

(30) Foreign Application Priority Data
Dec. 21, 2023 (MY) PI 2023007839

(51) Int. Cl. H01L 33/62; H01L 23/00; H01L 33/54

(52) U.S. Cl. CPC H10H 20/857; H01L 24/48; H01L 24/85; H10H 20/853; H01L 2224/48245; H01L 2224/48451; H01L 2224/48464; H01L 2224/85; H10H 20/0364

(57) ABSTRACT

An enhanced wire bond configuration for a light emitting diode (LED) package is presented herein. An optoelectronic component comprises a surface mountable package, the surface mountable package comprising: an LED chip that has been bonded, within a cavity of the surface mountable package, to a lead frame of the surface mountable package; a first bump that has been bonded onto a bond pad of the LED chip; a wire that has been ball bonded onto the lead frame; a wire stitch of the wire that has been formed on top of the first bump; and a second bump that has been bonded on top of the wire stitch. An encapsulant material including a defined softness can cover the LED chip, and can be added, injected, transfer-molded, and/or filled into the cavity. The defined softness can include a Shore hardness that is less than Shore 70A.

### RELATED APPLICATION

The subject patent application claims priority under 35 U.S.C. § 119 to Malaysia Pat. App. No. PI 2023007839, filed Dec. 21, 2023, and entitled “ENHANCED WIRE BOND CONFIGURATION FOR A LIGHT EMITTING DIODE PACKAGE”, the entirety of which application is hereby incorporated by reference herein.

### TECHNICAL FIELD

The subject disclosure generally relates to embodiments for an enhanced wire bond configuration for a light emitting diode (LED) package.

### BACKGROUND

Conventional LED technologies utilize a wire that is bonded to an LED chip of an LED package to form an electrical connection between the LED chip and a terminal of the LED package. In this regard, the wire is ball bonded from a lead frame of the package, and a stitch of the wire is formed directly on top of a bump that has been bonded to the LED chip. An external force that has been applied to the LED package (e.g., during handling of the LED package via a surface mount technology (SMT) pick-and-place operation and/or manual and handling of the LED package) can compromise a strength of a wire bond corresponding to the bump of the LED chip, and/or can cause the stich to break-causing a loss of electrical contact of the LED chip to the terminal of the LED package, e.g., leading to reduced and/or failed performance of the LED chip. In this regard, conventional LED technologies have had some drawbacks, some of which may be noted with reference to the various embodiments described herein below.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 illustrates a block diagram of a side view of a surface mountable package comprising an enhanced wire bond configuration for a light emitting diode (LED) chip that has been bonded within a cavity of the surface mountable package, in accordance with various example embodiments;

FIG. 2 illustrates a block diagram of a side view of an optoelectronic component comprising a surface mountable package that comprises an enhanced wire bond configuration for an LED chip that has been bonded within a cavity of the surface mountable package, in accordance with various example embodiments;

FIG. 3 illustrates a block diagram including an image of a surface mountable package comprising an enhanced wire bond configuration for an LED chip that has been bonded within a cavity of the surface mountable package, and an enlarged image of the enhanced wire bond configuration, in accordance with various example embodiments;

FIGS. 4 and 5 illustrate a method of manufacturing an optoelectronic component comprising a surface mountable package that comprises an enhanced wire bond configuration for an LED chip that has been bonded within a cavity of the surface mountable package, in accordance with various example embodiments; and

FIGS. 6 and 7 illustrate another method of manufacturing an optoelectronic component comprising a surface mountable package that comprises an enhanced wire bond configuration for an LED chip that has been bonded within a cavity of the surface mountable package, in accordance with various example embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, conventional LED technologies have had some drawbacks with respect to an external force being applied to an LED package, e.g., the external force compromising a strength of a wire bond corresponding to a bump of an LED chip of the LED package; causing a stitch of a wire formed on the bump to break; and/or causing the wire to break. On the other hand, various embodiments disclosed herein can prevent a strength of a wire bond of a wire that has been attached to a bump of an LED chip from being reduced, and/or can prevent a stitch of the wire from breaking in response to an external force being applied to the LED chip, e.g., during handling of the LED package via an SMT pick-and-place operation, and/or during manual handling of the LED package.

For example, in embodiment(s), an optoelectronic component comprises a surface mountable package, the surface mountable package comprising: an LED chip that has been bonded, within a cavity of the surface mountable package, to a lead frame of the surface mountable package; a first bump that has been bonded onto a bond pad of the LED chip; a wire that has been ball bonded onto the lead frame; a wire stitch of the wire that has been formed on top of the first bump; and a second bump that has been bonded on top of the wire stitch.

In other embodiment(s), the optoelectronic component further comprises an encapsulant material (e.g., a translucent or transparent encapsulant material/encapsulant) that has been added, injected, transfer-molded, and/or filled into the cavity to cover the LED chip—the encapsulant material comprising a defined softness, e.g., a Shore hardness that is less than Shore A70 or Shore 70A.

In yet other embodiment(s), a method of manufacturing an optoelectronic component including a surface mountable package comprises: bonding, within a cavity of the surface mountable package, an LED chip to a lead frame of the surface mountable package; bonding a first bump onto a bond pad of the LED chip; ball bonding a wire onto the lead frame; forming a wire stitch of the wire on top of the first bump; bonding a second bump on top of the wire stitch to facilitate an absorption, via the second bump, of an external force that has been applied to the optoelectronic component; adding, injecting, transfer-molding, and/or filling an encapsulant material of a defined softness, e.g., comprising a Shore hardness that is less than Shore A70 or Shore 70A, into the cavity—the encapsulant material covering the LED chip; and singulating the optoelectronic component from a panel comprising a group of optoelectronic components comprising the optoelectronic component.

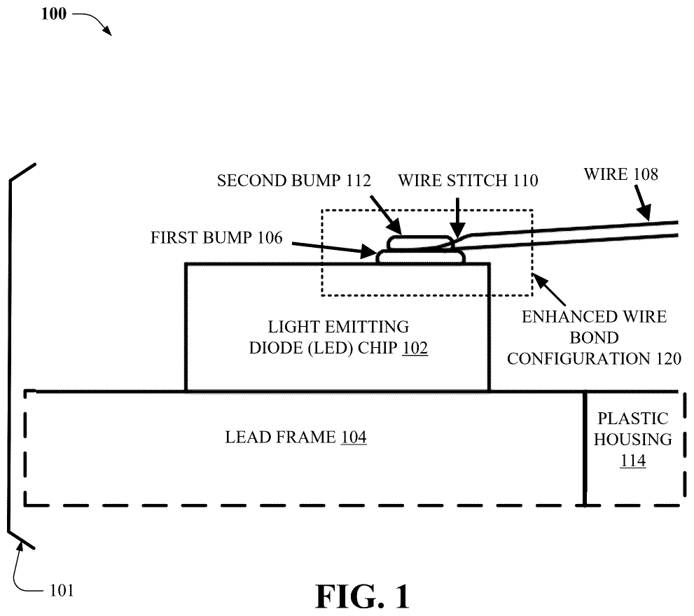

Referring now to FIGS. 1-3, various embodiments disclosed herein can improve LED chip performance with respect to, e.g., preserving a strength of a wire bond of a wire that has been attached to a bump of the LED chip, and/or preventing a stitch of the wire from breaking in response to an external force that has been applied to the LED chip.

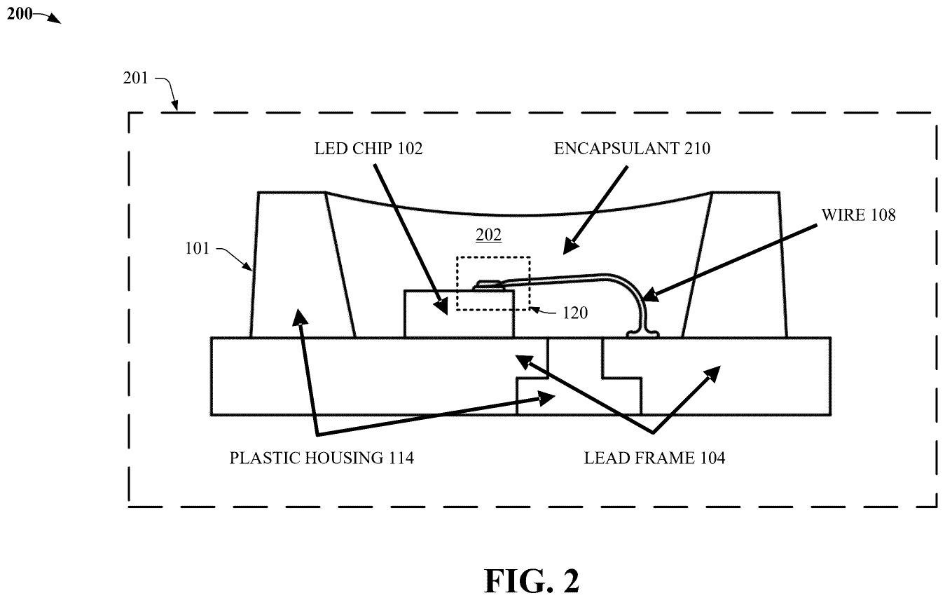

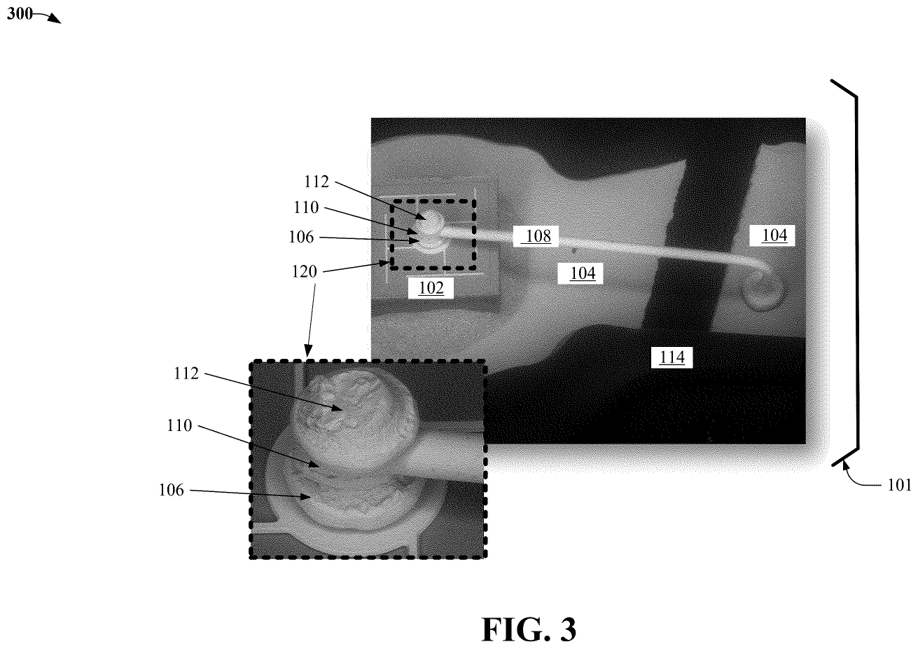

In this regard, FIG. 1 illustrates a block diagram (100) of a side view of a surface mountable package (101) comprising an enhanced wire bond configuration (120) for an LED chip (102) that has been bonded, within a cavity (202) of the surface mountable package, to a lead frame (104) of the surface mountable package; FIG. 2 illustrates a block diagram (200) of a side view of an optoelectronic component (201) comprising the surface mountable package; and FIG. 3 illustrates a block diagram (300) including an image of the surface mountable package, and an enlarged image of the enhanced wire bond configuration, in accordance with various example embodiment(s).

The surface mountable package comprises a plastic housing (114) that separates respective portions of the lead frame. A first portion of the respective portions of the lead frame corresponds to a bond pad (not shown) of the LED chip. A first bump (106) has been bonded onto the bond pad of the LED chip; and a wire (108) has been ball bonded onto a second portion of the respective portions of the lead frame.

A wire stitch (110) of the wire has been formed on top of the first bump; and a second bump (112) has been bonded on top of the wire stitch. An encapsulant material (e.g., encapsulant 210), e.g., a translucent or transparent encapsulant material comprising a defined softness (e.g., a Shore hardness that is less than Shore A70 or Shore 70A), has been added, injected, transfer molded, and/or filled into the cavity and covers the LED chip.

In embodiment(s), a light emitting surface of the encapsulant material facilitates a transmission, via the LED chip, of electromagnetic radiation comprising visible light, infrared light, and/or ultraviolet light.

In other embodiment(s), the second bump facilitates an absorption, via the encapsulant material, of an external force that has been applied to the optoelectronic component, e.g., the external force being applied to the LED package via manual handling of the LED package and/or via an SMT pick-and-place operation (e.g., utilizing a capillary). In embodiment(s), the external force that has been applied has been determined to be less than or equal to, e.g., within a defined percentage tolerance (e.g., 5%), a defined maximum applied force threshold.

In yet other embodiment(s), the absorption of the external force prevents the wire from being damaged and/or broken. In embodiment(s), the absorption of the external force prevents the capillary from damaging one or more portions of the wire that are located outside of the wire stitch. In other embodiment(s), the absorption of the external force prevents the wire stitch from being detached from the first bump.

In embodiment(s), a first diameter of the first bump is equal to or greater than a second diameter of the second bump. In this regard, in other embodiment(s), the first diameter of the first bump being equal to or greater than the second diameter of the second bump facilitates an enhancement of a visual inspection of anomalies of a connection of the wire stitch to the first bump and/or a formation of the wire stitch.

In yet other embodiment(s), a bump diameter of the first bump is greater than or equal to, within a defined percentage tolerance (e.g., 5%), 2.5 times a wire diameter of the wire, and the bump diameter of the first bump is less than or equal to, within the defined percentage tolerance, a bond pad diameter of the bond pad of the LED chip.

In embodiment(s), the bump diameter of the first bump is a first bump diameter; a second bump diameter of the second bump is greater than or equal to, within the defined percentage tolerance, 1.5 times the wire diameter of the wire; and the second bump diameter of the second bump is less than or equal to, within the defined percentage tolerance, the first bump diameter.

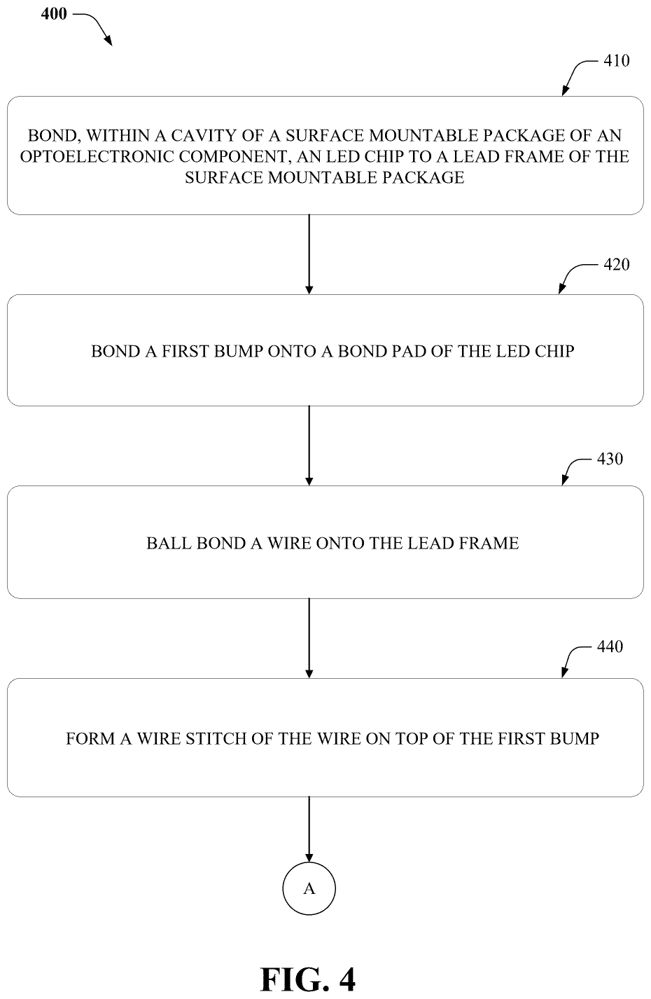

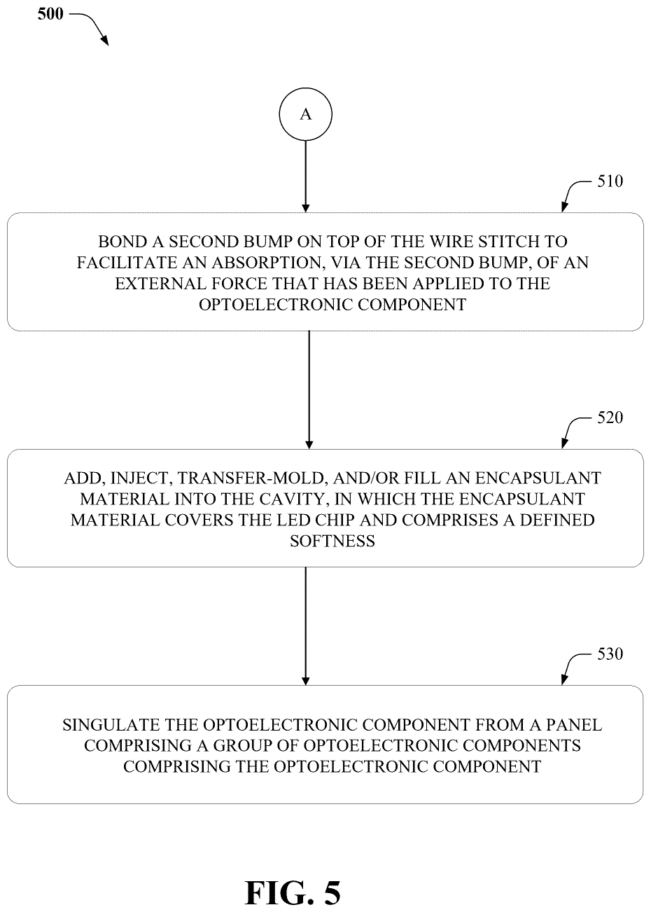

Referring now to FIGS. 4-5, a method (400-500) of manufacturing an optoelectronic component (201) comprising a surface mountable package (101) that comprises an enhanced wire bond configuration (120) for an LED chip (110) that has been bonded within a cavity (202) of the surface mountable package, in accordance with various example embodiments. At 410, the LED chip is bonded, within the cavity, to a lead frame (104) of the surface mountable package. At 420, a first bump (106) is bonded onto a bond pad of the LED chip. At 430, a wire (108) is ball bonded onto the lead frame. At 440, a wire stitch (110) of the wire is formed on top of the first bump.

At 510, a second bump (112) is bonded on top of the wire stitch to facilitate an absorption, via the second bump, of an external force that has been applied to the optoelectronic component. At 520, an encapsulant material (210) is added, injected, transfer-molded, and/or filled into the cavity—the encapsulant material covering the LED chip and comprising a defined softness (e.g., a Shore hardness that is less than Shore A70 or Shore 70A). At 530, the optoelectronic component is singulated from a panel comprising a group of optoelectronic components comprising the optoelectronic component.

In embodiment(s), a first diameter of the first bump is equal to or greater than a second diameter of the second bump to facilitate an enhancement of a visual inspection of anomalies of a connection of the wire stitch to the first bump and/or a formation of the wire stitch on top of the first bump.

In other embodiment(s), a bump diameter of the first bump is greater than or equal to, within a defined percentage tolerance (e.g., 5%), 2.5 times a wire diameter of the wire, and the bump diameter of the first bump is less than or equal to, within the defined percentage tolerance, a bond pad diameter of the bond pad of the LED chip.

In yet other embodiment(s), the bump diameter of the first bump is a first bump diameter; a second bump diameter of the second bump is greater than or equal to, within the defined percentage tolerance, 1.5 times the wire diameter of the wire; and the second bump diameter of the second bump is less than or equal to, within the defined percentage tolerance, the first bump diameter of the first bump.

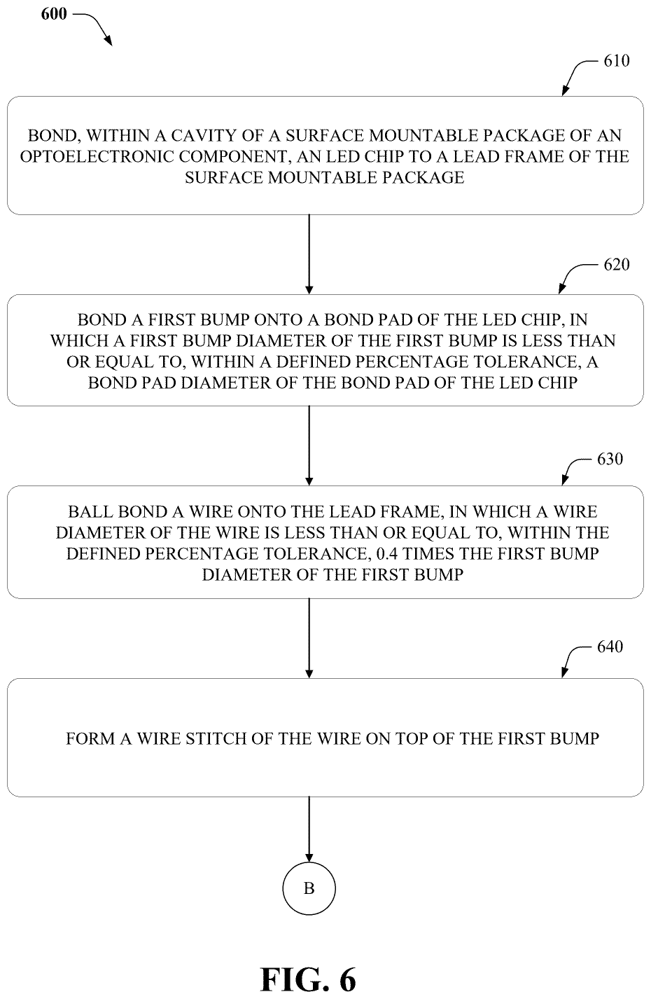

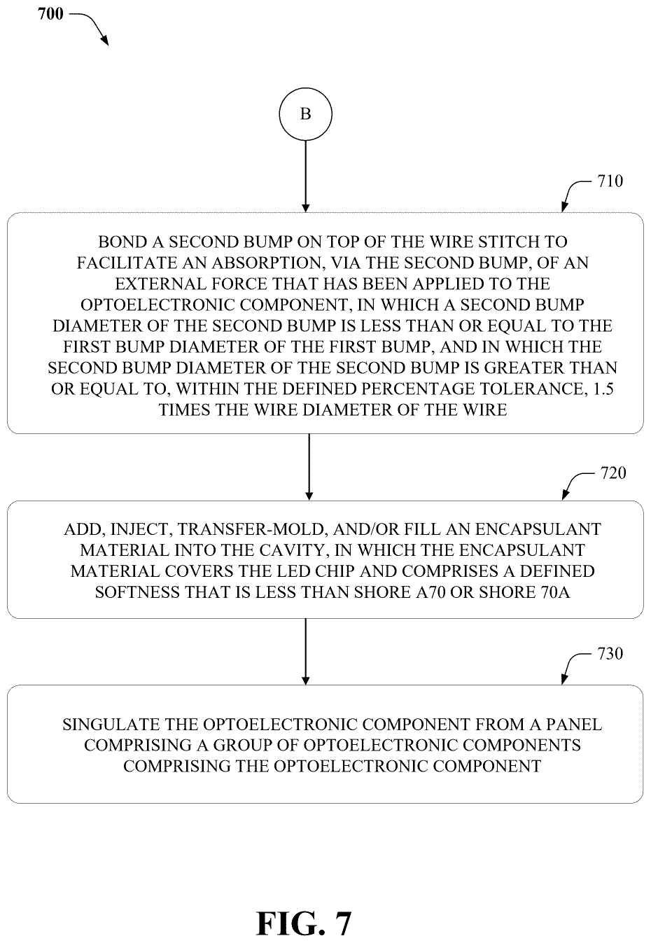

FIGS. 6-7 illustrate another method (600-700) of manufacturing an optoelectronic component (201) comprising a surface mountable package (101) that comprises an enhanced wire bond configuration (120) for an LED chip (102) that has been bonded within a cavity (202) of the surface mountable package, in accordance with various example embodiments.

At 610, the LED chip is bonded, within the cavity, to a lead frame (104) of the surface mountable package. At 620, a first bump (106) is bonded onto a bond pad of the LED chip, in which a first bump diameter of the first bump is less than or equal to, within a defined percentage tolerance (e.g., 5%), a bond pad diameter of the bond pad.

At 630, a wire (108) is ball bonded onto the lead frame, in which a wire diameter of the wire is less than or equal to, within the defined percentage tolerance, 0.4 times the first bump diameter of the first bump (e.g., the first bump diameter of the first bump being greater than or equal to, within the defined percentage tolerance, 2.5 times the wire diameter of the wire). At 640, a wire stitch (110) of the wire is formed on top of the first bump.

At 710, a second bump (112) is bonded on top of the wire stitch to facilitate an absorption, via the second bump, of an external force that has been applied to the optoelectronic component, in which a second bump diameter of the second bump is less than or equal to the first bump diameter of the first bump, and in which the second bump diameter of the second bump is greater than or equal to, within the defined percentage tolerance, 1.5 times the wire diameter of the wire.

At 720, an encapsulant material (210) is added, injected, transfer-molded, and/or filled into the cavity—the encapsulant material covering the LED chip and comprising a defined softness (e.g., a Shore hardness that is less than Shore A70 or Shore 70A). At 730, the optoelectronic component is singulated from a panel comprising a group of optoelectronic components comprising the optoelectronic component.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

Further, to the extent that the terms “includes,” “has,” “contains,” and other similar words are used in either the detailed description or the appended claims, such terms are intended to be inclusive-in a manner similar to the term “comprising” as an open transition word-without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. An optoelectronic component comprising a surface mountable package, the surface mountable package comprising:
a light emitting diode (LED) chip that has been bonded, within a cavity of the surface mountable package, to a lead frame of the surface mountable package;
a first bump that has been bonded onto a bond pad of the LED chip;
a wire that has been ball bonded onto the lead frame;
a wire stitch of the wire that has been formed on top of the first bump; and
a second bump that has been bonded on top of the wire stitch.

2. The optoelectronic component of claim 1, further comprising:
an encapsulant material covering the LED chip, wherein the encapsulant material comprises a defined softness.

3. The optoelectronic component of claim 2, wherein the defined softness comprises a Shore hardness that is less than Shore A70 or Shore 70A.

4. The optoelectronic component of claim 2, wherein the encapsulant material has been at least one of added, injected, transfer-molded, or filled into the cavity.

5. The optoelectronic component of claim 2, wherein the encapsulant material is translucent or transparent.

6. The optoelectronic component of claim 2, wherein a light emitting surface of the encapsulant material facilitates a transmission, via the LED chip, of electromagnetic radiation comprising at least one of visible light, infrared light, or ultraviolet light.

7. The optoelectronic component of claim 2, wherein the second bump facilitates an absorption, via the encapsulant material, of an external force that has been applied to the optoelectronic component, and wherein the external force is less than or equal to a defined maximum applied force threshold.

8. The optoelectronic component of claim 7, wherein the absorption of the external force prevents the wire from being at least one of damaged or broken.

9. The optoelectronic component of claim 7, wherein the external force has been applied, via a capillary, to the LED package.

10. The optoelectronic component of claim 9, wherein the absorption of the external force prevents the capillary from damaging one or more portions of the wire that are located outside of the wire stitch.

11. The optoelectronic component of claim 7, wherein the absorption of the external force prevents the wire stitch from being detached from the first bump.

12. The optoelectronic component of claim 1, wherein a first diameter of the first bump is equal to or greater than a second diameter of the second bump.

13. The optoelectronic component of claim 12, wherein the first diameter of the first bump being equal to or greater than the second diameter of the second bump facilitates an enhancement of a visual inspection of anomalies of at least one of a connection of the wire stitch to the first bump or a formation of the wire stitch.

14. The optoelectronic component of claim 1, wherein a bump diameter of the first bump is greater than or equal to, within a defined percentage tolerance, 2.5 times a wire diameter of the wire, and wherein the bump diameter of the first bump is less than or equal to, within the defined percentage tolerance, a bond pad diameter of the bond pad of the LED chip.

15. The optoelectronic component of claim 14, wherein the bump diameter of the first bump is a first bump diameter, wherein a second bump diameter of the second bump is greater than or equal to, within the defined percentage tolerance, 1.5 times the wire diameter of the wire, and wherein the second bump diameter of the second bump is less than or equal to, within the defined percentage tolerance, the first bump diameter.

16. A method of manufacturing an optoelectronic component comprising a surface mountable package, the method comprising:
bonding, within a cavity of the surface mountable package, a light emitting diode (LED) chip to a lead frame of the surface mountable package;
bonding a first bump onto a bond pad of the LED chip;
ball bonding a wire onto the lead frame;
forming a wire stitch of the wire on top of the first bump;
bonding a second bump on top of the wire stitch to facilitate an absorption, via the second bump, of an external force that has been applied to the optoelectronic component;
at least one of adding, injecting, transfer-molding, or filling an encapsulant material into the cavity, wherein the encapsulant material covers the LED chip and comprises a defined softness; and
singulating the optoelectronic component from a panel comprising a group of optoelectronic components comprising the optoelectronic component.

17. The method of manufacturing the optoelectronic component of claim 16, wherein the defined softness comprises a Shore hardness that is less than Shore A70 or Shore 70A.

18. The method of manufacturing the optoelectronic component of claim 16, wherein a first diameter of the first bump is equal to or greater than a second diameter of the second bump to facilitate an enhancement of a visual inspection of anomalies of at least one of a connection of the wire stitch to the first bump or a formation of the wire stitch on top of the first bump.

19. The method of manufacturing the optoelectronic component of claim 16, wherein a bump diameter of the first bump is greater than or equal to, within a defined percentage tolerance, 2.5 times a wire diameter of the wire, and wherein the bump diameter of the first bump is less than or equal to, within the defined percentage tolerance, a bond pad diameter of the bond pad of the LED chip.

20. The method of manufacturing the optoelectronic component of claim 19, wherein the bump diameter of the first bump is a first bump diameter, wherein a second bump diameter of the second bump is greater than or equal to, within the defined percentage tolerance, 1.5 times the wire diameter of the wire, and wherein the second bump diameter of the second bump is less than or equal to, within the defined percentage tolerance, the first bump diameter of the first bump.
